(19) United States
(12) Patent Application Publication
(10) Pub. No.: US 2024/0229294 A1
(43) Pub. Date: Jul. 11, 2024

(54) COMPARTMENTALIZED SUMP AND GAS FLOW SYSTEM FOR SILICON RIBBON PRODUCTION

(71) Applicant: LEADING EDGE CRYSTAL TECHNOLOGIES, INC., Wilmington, MA (US)

(72) Inventors: Nathan STODDARD, Chalfont, PA (US); Parthiv DAGGOLU, Danvers, MA (US); Alexander MARTINEZ, Woburn, MA (US); Peter KELLERMAN, Essex, MA (US)

(21) Appl. No.: 18/558,998

(22) PCT Filed: May 3, 2022
(86) PCT No.: PCT/US2022/027530

§ 371 Date: Nov. 3, 2023

Related U.S. Application Data
(60) Provisional application No. 63/183,605, filed on May 3, 2021.

(51) Int. Cl. C30B 27/02; C30B 29/06; C30B 29/64

(52) U.S. Cl. CPC C30B 27/02; C30B 29/06; C30B 29/64

(57) ABSTRACT

An apparatus for forming a crystalline ribbon grown on a surface of a melt includes an inner chamber. A crucible in the inner chamber is configured to hold a melt. A cold initializer in the inner chamber faces an exposed surface of the melt. A process gas feed is in fluid communication with a process gas inlet of the inner chamber. An outer chamber surrounds at least part of the inner chamber and defines an opening for the process gas feed and a sump inlet. A sump gas feed is in fluid communication with the sump inlet. The sump gas feed is configured to deliver a sump gas to the sump region. The sump region also can include heaters and insulation.

### CROSS-REFERENCE TO RELATED APPLICATIONS

This application claims priority to the provisional patent application filed May 3, 2021 and assigned U.S. App. No. 63/183,605, the disclosure of which is hereby incorporated by reference.

### STATEMENT REGARDING FEDERALLY-SPONSORED RESEARCH OR DEVELOPMENT

This invention was made with government support under contract DOE-EE00008971 awarded by the U.S. Department of Energy. The government has certain rights in the invention.

### FIELD OF THE DISCLOSURE

This disclosure relates to production of silicon ribbons.

### BACKGROUND OF THE DISCLOSURE

Silicon wafers or sheets are used in, for example, the integrated circuit, battery, or solar cell industries. Previously, cut silicon wafers were made by wire-sawing large silicon ingots or boules made from the Float-Zone (FZ) process, Czochralski (Cz) process, Modified Czochralski process (MCz) where magnetic fields are used to control oxygen, or a directional solidification (“cast”) process.

A single-step, continuous process that directly produces single crystal wafers from polysilicon feedstock is desirable. Continuous, direct wafer processes that produce net-shaped wafers eliminate many costly downstream process steps (e.g., wire sawing) and can produce wafers with more uniform properties than discrete Cz ingot production. Unfortunately, historic direct silicon wafer processes have not been able to create the full-size single crystal silicon wafers. Specifically, vertical ribbon processes like Edge-Fed Growth and String Ribbon as well as horizontal substrate processes like Ribbon Growth on Substrate or Direct Wafer produce multicrystalline wafers with typical crystal grain sizes from 1 mm to 20 mm. One vertical ribbon process known as Dendritic Web showed ability to make single crystal wafers, but the process could only yield narrow material (e.g., approximately 2 inches wide) before becoming unstable. Solar and semiconductor devices require larger wafers (>5 inches) for economic device manufacturing. Directly making single-crystal silicon wafers by epitaxially growing full-size silicon wafers on a porous silicon substrate that is then mechanically separated from the porous substrate also has been performed. Producing a wafer from epitaxial growth is slow, expensive and subject to minority carrier lifetime (MCL)-limiting defects such as stacking faults and dislocations.

One promising method that has been investigated to lower the cost of materials for solar cells is the floating silicon method (FSM), which is a type of horizontal ribbon growth (HRG) technique where crystalline sheets are pulled horizontally along the surface of a melt. In this method, a portion of a melt surface is cooled sufficiently to locally initiate crystallization with the aid of a seed, which may be then drawn along the melt surface (while floating) to form a monocrystalline sheet. The local cooling may be accomplished by employing a device that rapidly removes heat above the region of the melt surface where crystallization is initiated. Under proper conditions, a stable leading edge of the crystalline sheet may be established in this region. Formation of a faceted leading edge is not obtained in Cz or other ribbon growth processes, and can add inherent stability to the growth interface.

In order to sustain the growth of this faceted leading edge in a steady-state condition with the growth speed matching the pull speed of the monocrystalline sheet or “ribbon,” intense cooling may be applied by a crystallizer in the crystallization region. This may result in the formation of a monocrystalline sheet whose initial thickness is commensurate with the width of the applied intensive cooling profile. The initial thickness is often on the order of 1-2 mm in the case of silicon ribbon growth. For applications such as forming solar cells from a monocrystalline sheet or ribbon, a target thickness may be on the order of 200 μm or less. This necessitates a reduction in thickness of the initially-formed ribbon. This may be accomplished by heating the ribbon over a region of a crucible containing the melt as the ribbon is pulled in a pulling direction. As the ribbon is drawn through the region while the ribbon is in contact with the melt, a given thickness of the ribbon may melt back, thus reducing the ribbon thickness to a target thickness. This melt-back approach is particularly well-suited in FSM, wherein a silicon sheet is formed floating on the surface of a silicon melt according to the procedures generally described above.

It is difficult to avoid contamination and gas loss in systems that form silicon ribbons. Improved techniques to form thin and wide ribbons or wafers are needed.

### BRIEF SUMMARY OF THE DISCLOSURE

An apparatus for forming a crystalline ribbon grown on a surface of a melt is provided in a first embodiment. The apparatus includes an inner chamber defining a process gas inlet, an exhaust outlet, and a silicon ribbon exit; a crucible configured to hold a melt; a cold initializer facing an exposed surface of the melt; a process gas feed in fluid communication with the process gas inlet; an outer chamber that surrounds at least part of the inner chamber and defines an opening for the process gas feed and a sump inlet; a plurality of heaters disposed in a sump region between an interior surface of the outer chamber and an exterior surface of the inner chamber; and a sump gas feed in fluid communication with the sump inlet. The crucible is disposed in a volume of the inner chamber. The cold initializer is disposed in a volume of the inner chamber. The sump gas feed is configured to deliver a sump gas to the sump region.

The apparatus can include insulation disposed in the sump region.

The outer chamber can define a sump exhaust in fluid communication with the sump region.

The volume of the inner chamber can be sealed from the sump region.

The apparatus can include a process gas source in fluid communication with the process gas feed. The process gas source includes helium and/or hydrogen.

The apparatus can include a sump gas source in fluid communication with the sump gas feed. The sump gas source includes argon.

An interior surface of the inner chamber can include a coating. The coating can include SiC, BN, and/or TaC.

The outer chamber can define an opening for the exhaust outlet. In an instance, the exhaust outlet is configured to remove evaporated gas and the process gas from the volume of the inner chamber. The apparatus can further include a filtering system configured to remove the evaporated gas from the process gas and a recycle feed configured to recycle process gas from the filter.

The apparatus can include a gas curtain at the silicon ribbon exit. The gas curtain can use nitrogen.

A method is provided in a second embodiment. The method includes providing a melt in a crucible. The crucible is disposed in an inner chamber. The inner chamber is disposed at least partly within an outer chamber. A ribbon floating on the melt is formed using a cold initializer facing an exposed surface of the melt. The ribbon is single crystal. A process gas is directed to a volume of the inner chamber through the inner chamber and the outer chamber. A sump gas is directed to a sump region between the inner chamber and the outer chamber.

The method can include pulling the ribbon through a silicon ribbon exit defined by the inner chamber. The ribbon is formed at a same rate as the pulling. In an instance, a gas curtain is applied at the silicon ribbon exit. The gas curtain can use nitrogen.

The method can include separating the ribbon from the melt at a wall of the crucible where a stable meniscus forms.

The method can include applying heat to a volume of the inner chamber using heaters in the sump region.

The volume of the inner chamber can be sealed from the sump region.

The process gas can include helium and/or hydrogen. The sump gas can include argon.

The method can include removing evaporated gas and the process gas from a volume of the inner chamber through an exhaust outlet. The method can further include removing the evaporated gas from the process gas using a filtering system and recycling the process gas from the filtering system.

### DESCRIPTION OF THE DRAWINGS

For a fuller understanding of the nature and objects of the disclosure, reference should be made to the following detailed description taken in conjunction with the accompanying drawings, in which:

FIG. 1 is a an embodiment of a system in accordance with the present disclosure;

FIG. 2 is a block system diagram showing an embodiment of the system of FIG. 1; and

FIG. 3 is a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein can be used with crystal growth processes that produce vapor and/or use more than one process gas. For example, silicon in a quartz crucible produces SiO vapor, which condenses at temperatures less than 1250° C. SiO and carbon can react at these temperatures to form SiC on various surfaces of the system. While SiO is specifically described, this can similarly refer to other evaporated species. In another example, sapphire in a molybdenum crucible can produce AlOₓ vapor. In yet another example, III-V compounds like GaAs, GaSb, or InP can cause evaporated P, As, or Sb during crystal growth. These vapors can damage components in the system and can complicate gas flows.

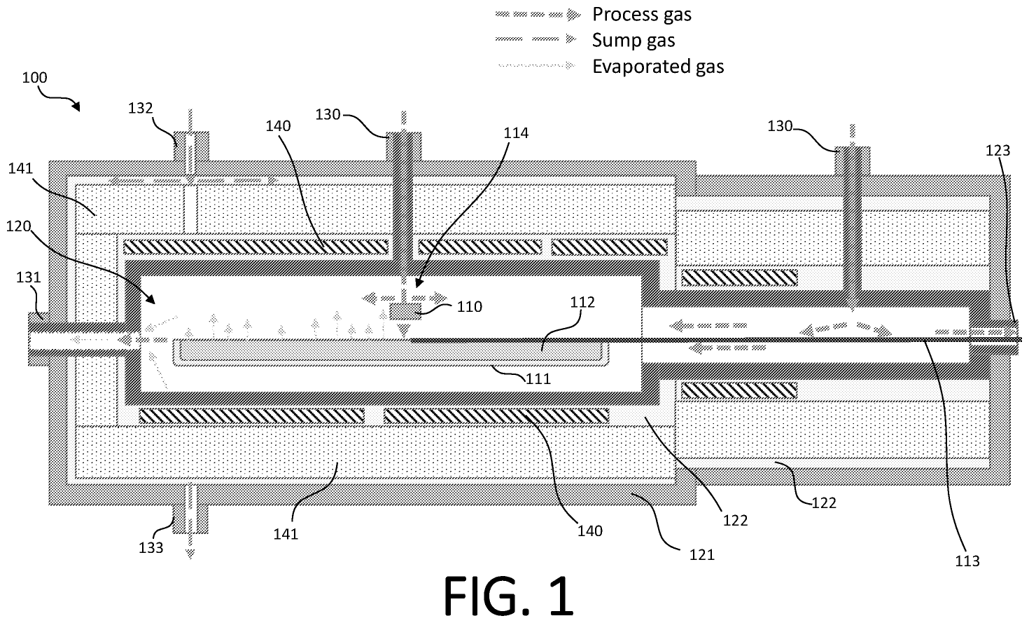

A system 100 for wafer production, such as that illustrated in FIG. 1, can include a crucible 111 for housing a melt 112 and a cold block 110 having a cold block surface that directly faces an exposed surface of the melt 112. The cold block 110 is part of a cold initializer 114. The cold block 110 is configured to generate a cold block temperature at the cold block surface (e.g., facing the melt 112) that is lower than a melt temperature of the melt 112 at the exposed surface whereby a ribbon 113 is formed on the melt 112. In an embodiment, the cold initializer 114 also can provide a cooling jet (e.g., the jet of process gas directed at the melt 112) to assist in formation or initialization of the solid ribbon 113. The cooling jet can use the process gas or other gases. Thus, the cold initializer 114 can use radiative and/or convective cooling. The cold block 110 can be water-cooled or cooled by another suitable method.

During operation a melt 112 is provided in the crucible 111. The melt can be silicon, germanium, or other materials. A ribbon 113 is formed horizontally on the melt 112 using the cold initializer 114 with a cold block 110 surface that directly faces an exposed surface of the melt 112. A uniform melt-back heater and cooled thinning controller or a segmented thinning controller (not illustrated) can adjust the thickness of the ribbon 113 in the melt 112 after it is formed. Such components are disclosed in PCT applications WO2021/168244 and WO2021/168256, the disclosures of which are incorporated by reference in their entirety. A cooled thinning controller can include a segmented cooled thinning controller disposed above the crucible 111 on a side of the crucible with the cold initializer 114 and a uniform melt-back heater disposed below of the crucible 111 opposite the cooled thinning controller. The segmented cooled thinning controller is configured to cool a surface of the melt 112. The uniform melt-back heater is configured to uniform heat to the melt 112. The segmented thinning controller is configured to adjust a width and a thickness of a ribbon 113 formed on the melt 112.

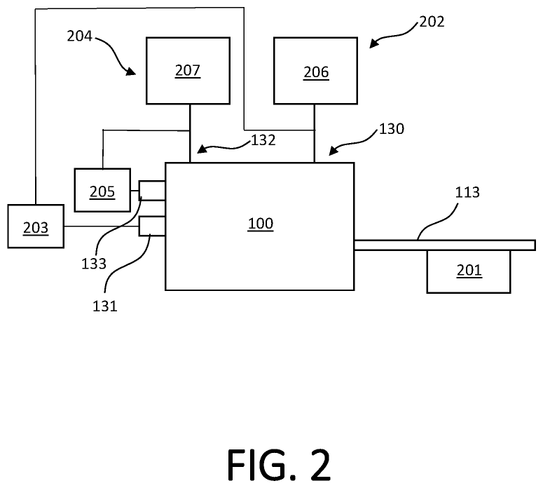

The ribbon 113 is pulled from the melt 112 at a low angle off the surface of the melt 112 using a puller 201 (shown in FIG. 2), which may be a mechanical ribbon pulling system. The ribbon 113 may be pulled from the crucible 11 at a 0° angle or at a small angle relative to a surface of the melt 112 (e.g., less than 10°). The ribbon 113 can be supported and singulated into wafers downstream of the crucible 111.

An inner chamber 120 defines at least one process gas inlet 130, an exhaust outlet 131, and a silicon ribbon exit 123. Optionally, other features may be included, such as optical windows, feedstock entry ports, and measurement devices. While two process gas inlets 130 and one exhaust outlet 131 are shown, more or fewer process gas inlets 130 and exhaust outlets 131 are possible. With respect to the feedstock entry ports, there may be an access point to insert feedstock into the inner chamber 120, such as to the crucible 111 in the growth zone. The access point can use a purge gas to maintain the environment in the inner chamber 120.

The crucible 111 and cold block 110 are disposed in a volume of the inner chamber 120. The inner chamber 120 volume can range from about 1 liter to about 1000 liters, depending on the crucible 111 size. A process gas feed 202, which can include piping, valves, and/or one or more gas storage tanks 206 is in fluid communication with the process gas inlet 130. The gas storage tank 206 is an example of a process gas source. The exhaust outlet 113 is configured to remove evaporated gas and process gas from the volume of the inner chamber 120.

As shown in FIG. 2, a filtering system 203 can be in fluid communication to the exhaust outlet 131. The filtering system 203 can remove SiO from evaporated gases from the inner chamber 120. The filtering system 203 also can remove moisture from the evaporated gases. A recycle feed can recycle process gas from the filtering system 203 by directing it to the process gas inlet 130 or to the process gas feed 202. This recycled process gas has most or all of the SiO removed using the filtering system 203. The filtering system 203 can include a high surface area cold trap to condense the evaporated material, but also can include the use of filter media to trap airborne particles, such as a HEPA filter. The filtering system 203 can remove SiO (or other evaporated gases) from the process gas with an effectiveness from 50% to greater than 99%. In an example, a high surface area cold trap can be approximately 80% effective at removing SiO from the process gas. In another example, a high surface area cold trap with a HEPA filter can be approximately 99.9% effective at removing SiO from the process gas.

A volume is formed in the inner chamber 120 to hold the evaporated gas (e.g., SiO, AlOₓ) and shunt it out of the system 100. Any shunting or removal via the exhaust outlet 113 can be transitioned from hot to cold. Separate zones can be used to keep gases apart, which can improve gas separation in the filtering system and recycle feed. These zones are typically separated by a region through which gas diffusion is reduced, such as by restricting the gas passage cross-section while lengthening the gas passage length. Such a passage can be positioned, for example, closely around a ribbon being extracted from the furnace. This passage may be composed of fixed-size walls, may be partially composed of moving walls or bladder-like devices, or may use other methods of dynamically controlling the passage orifice. This gas-restricting transition zone can be combined with a temperature gradient as part of the overall ribbon cooling process.

The evaporated gases typically react with graphite, which is usually used in heaters 140 or insulation 141 in hot zones of the system 100. The various heaters 140 and insulation 141 are shown in FIG. 1 with similar hatching. Different configurations of the heaters 140 and insulation 141 than at in FIG. 1 are possible. Hard graphite and carbon fiber can be used in heaters 140. Fibrous graphite can be used in insulation 141. Blocking evaporated gases from interaction with the graphite in these hot zone components can avoid the need to coat graphite with SiC, pyrolytic carbon, TaC or other coatings, which reduces cost. Blocking evaporated gases from interaction with insulation 141 also extends the life of the insulation 141 and prevents reductions in its efficacy over time.

An interior surface of the inner chamber 120 can include a coating, including some or all otherwise unprotected reactive surfaces (especially graphite) on the interior surfaces of the inner chamber 120. The coating can include SiC, pyrolytic carbon, BN, TaC, and other thermally-stable, chemically-passivating options. These coatings may not be present in the sump region between the inner chamber 120 and outer chamber 121, which can reduce cost. These coatings can prevent SiO from condensing on and/or reacting with graphite parts or other components. In the case of silicon-quartz-SiO, preventing SiO from reacting with carbon also eliminates the production of carbon monoxide (CO) gas, reducing another important contaminant. CO can adsorb to the melt 112 surface, introducing carbon to the melt 112, or can react directly on the surface of hot solid silicon of the ribbon 113, forming an SiOₓC_{y} coating that is detrimental to the produced material.

An outer (furnace) chamber 121 surrounds at least part of or a majority of the inner chamber 120. The outer chamber 121 also can entirely surround the inner chamber 120 if the outlets are still left open. The outer chamber 121 can define an opening for the process gas feed 130 and a sump inlet 132. The outer chamber 121 also can define an opening for the silicon ribbon exit 123 or other devices, such as for the feedstock entry ports, measurement devices, optical windows, or other parts of the system 100.

The outer chamber 121 also can define one or more sump exhausts 133 in fluid communication with the sump region 122. The sump exhaust 133 can remove gases from the sump region 122.

The outer chamber 121 also can define one or more openings for the exhaust outlet 131 from the inner chamber 120. Transporting SiO or other evaporated gases though the exhaust outlet 131 can enable preferential deposition in a trap or filter. The exhaust outlet 131 may be operated above 1250° C. until a designated transition area to prevent clogging.

While the sump region 122 is illustrated in FIG. 1 as above and below the inner chamber 120, the sump region 122 also may extend into and out of the page around the inner chamber 120.

A sump region 122 is between an interior surface of the outer chamber 121 and an exterior surface of the inner chamber 120. Thus, the sump region 122 is a volume between the outer chamber 121 and inner chamber 120. The sump region 122 volume may be only slightly larger than the size of the insulation 141 and heaters 140 (e.g., having a buffer zone from 5 mm to 50 mm). As shown in FIG. 2, a sump gas feed 204, which can include piping, valves, and/or one or more gas storage tanks 207, is in fluid communication with the sump inlet 132. The gas storage tank 207 is an example of a sump gas source. The sump gas feed is configured to deliver a sump gas to the sump region 122.

The volume of the inner chamber 120 can be sealed from the sump region 122. Sealing off areas in a hot zone can be accomplished with spring seals holding butt-end connections and threaded connections between like materials can help maintain a proper gas seal. A filtering system 205 and/or recycle feed can recycle sump gas from the sump exhaust 133 to the sump inlet 132. The sump region 122 may only need a small feed of gas in order to maintain any desired pressure differentials, and exhausted sump gas may need little conditioning to be reused. The amount of sump gas used is typically less than the process gas that is used. The filtering system 205 can remove impurities from the sump gas with an effectiveness from 50% to greater than 99%.

The inner chamber 120 can be sealed from the sump region 122 with an effectiveness of greater than 75%, greater than 90%, greater than 95%, greater than 96%, greater than 97%, greater than 98%, or greater than 99%. In an embodiment, effective sealing of approximately 100% between the inner chamber 120 and the sump region 122 can be achieved.

Turning back to FIG. 1, one or more heaters 140 are disposed in the sump region 122. Insulation 141 also can be disposed in the sump region 122. Keeping evaporated gases away from the sump region 122 can reduce cost and improve hot zone longevity.

A gas storage tank 206 for process gas can be in fluid communication with the process gas feed 202. The gas storage tank 206 can include helium and/or hydrogen, though other gases are possible such as argon, nitrogen, neon, functional gases like chlorine, or dopant-bearing gases like POCl₃. Helium and hydrogen may be used for jet-based cooling of a ribbon 113 using the cold initializer 114, but helium tends to be expensive and hydrogen is volatile in air. Both helium and hydrogen can reduce efficacy of the fiber insulation 141 in the sump region 122, but the design of the system 100 in FIG. 1 separates the helium or hydrogen from the insulation 141. The cooling process gas can be introduced at a temperature typically >100 K less than the melting temperature of the material. The cooling gas can be >500 K less, or even >1200 K less than the melting temperature of the material. Flow rates for the process gas can range from low values of approximately 1 SLM (liters/min at standard temperature and pressure) up to values as high as approximately 100-200 SLM.

A gas storage tank 207 for sump gas can be in fluid communication with the sump gas feed 204. The gas storage tank 207 can include argon, though other gases such as nitrogen, forming gas, or air are possible. Argon is less expensive than helium, but may not be equally effective for jet-based cooling of a ribbon 113. It also can be difficult to separate argon from helium. Therefore, keeping separate volumes of sump gas and process gas enables easier recycling of the process gas. The sump gas can be conveniently introduced on the cold side of the insulation, so no temperature conditioning may be necessary. The flow rate of the sump gas for sump purging can be from 1 SLM to 50 SLM. The sump gas flow can prevent outside air from diffusing into the system 100.

A gas curtain (not illustrated) can be positioned at the silicon ribbon exit 123 to prevent gas exchange through the silicon ribbon exit 123. For example, this can prevent helium or other process gases from escaping from the inner chamber 120. The gas curtain can use nitrogen, process gas, or other gases.

The embodiments disclosed herein can control the ambient environment around the ribbon 113 at high temperatures (e.g., up to 1500° C. or 1600° C.). Examples of the ambient temperature around the ribbon 113 can be from 1200° C. to 1414° C., 1200° C. to 1400° C., or from 1414° C. to 1450° C., though other ranges are possible. Relevant atmospheric pressures include low sub-atmospheric pressures (e.g., 0.01 atm) to positive-pressure systems (e.g., 5 atm). Further, the gas flow profiles around the ribbon surfaces can minimize metallic contamination via gas transport. There may be a pressure difference between the inner chamber 120 and the sump region 122 of up to 500 mBar (e.g., less than 100 mBar).

The solid ribbon 113 can separate over the edge of the crucible 111 at a slightly raised height of approximately 0.2 mm to 2 mm, which can ensure that a stable meniscus is maintained and that the melt 112 does not spill over the lip of the crucible 111 during separation. The crucible 111 edge also can be shaped to include pinning features to increase meniscus or capillary stability. The gas pressure on the meniscus between the ribbon 113 surface and the crucible 111 can be increased to increase meniscus stability. One example on how to increase gas pressure is to locally focus an impinging jet directly at this meniscus formed between the edge of the crucible 111 and the ribbon 113 surface.

As the ribbon 113 travels from the cold block 110 to where it reaches room temperature, the ribbon 113 is mechanically supported to minimize metallic contamination and the generation of defects, such as with ribbon support. Mechanically deflecting a thin ribbon 113 at high temperature can mechanically yield (i.e. plastically deform) the ribbon 113 and give rise to undesirable crystal defects such as dislocations. Physical contact with the ribbon 113 can locally result in undesirable slip, dislocations, and metallic contamination. As the ribbon 113 floats on the melt 112 surface, a mechanism to support the ribbon 113 over the melt 112 is optional. The ribbon 113 can be supported as it separates over the edge of the crucible 111 because that is where it is expected to experience the most mechanical deflection. The ribbon 113 can be supported during the pulling after the ribbon 113 is separated from the melt via several approaches, including gas flow levitation and/or a mechanical support. First, the ribbon 113 can be levitated by directed gas flows that create local high or low pressures on the ribbon surface to support the ribbon 113, which may use the process gas. Examples of gas flow levitation approaches can include Bernoulli grippers, gas bearings, air-hockey tables, or other techniques that use gas pressure. Another approach is to mechanically support the ribbon 113 with, for example, rollers or sliding rails. To minimize deleterious effects with this contact approach, the contact pressure between these supports and the ribbon surface may be minimized. The supports may be made of high temperature semiconductor-grade materials that do not readily contaminate silicon like silicon carbide, silicon nitride, quartz, or silicon. Deflection of the ribbon 113 may be minimized to prevent the ribbon 113 from mechanically yielding, warping, or producing structural defects.

After the ribbon 113 is cooled to approximately room temperature, the ribbon 113 can be singulated into discrete wafers. The wafers can be rectangular, square, pseudo square, circular, or any geometry that can be cut from a ribbon. Singulation can be performed by traditional techniques like laser scribing and cleaving, laser ablation, and mechanical scribing and cleaving. The final discrete wafer lateral dimensions can range from 1 cm to 50 cm (e.g., 1-45 cm or 20-50 cm), with thickness from 50 microns to 5 mm having a uniform thickness (e.g., low total thickness variation (TTV)) or a tailored thickness gradient.

The wafers can then be further processed or marked to generate additional features or material properties for the final semiconductor devices or solar cells. In an example, the wafers 18 can be ground, polished, thinned, or textured with chemicals or mechanical abrasion. In another example, the wafers can be either chemically textured or mechanically polished to create the desired final surface roughness. Material or geometry features can be added to the surface or in the bulk create the final desired devices. Example final products can include but are not limited to solar cells, MOSFETs, or anodes for lithium-ion batteries.

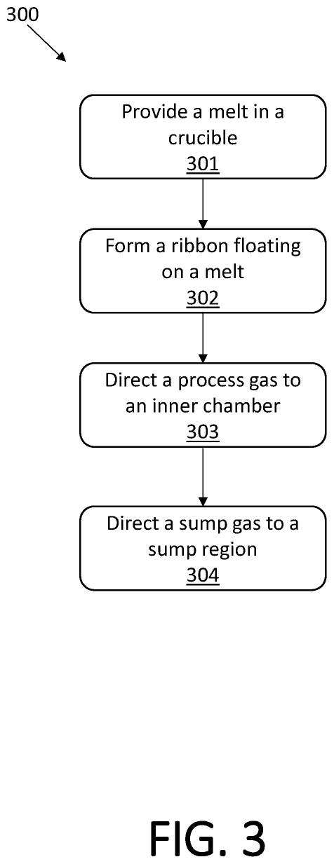

FIG. 3 is a flowchart of a method 300, which can be used with the system 100 of FIG. 1. A melt is provided in a crucible at 301. The crucible is disposed in an inner chamber. The inner chamber is disposed at least partly within an outer chamber (e.g., fully within the outer chamber except for the various apertures and access points). At 302, a ribbon floating in the melt is formed using a cold initializer facing an exposed surface of the melt. The ribbon may be single crystal, such as single crystal silicon.

At 303, a process gas is directed to a volume of the inner chamber through the inner chamber and the outer chamber. The process gas can include helium and/or hydrogen.

At 304, a sump gas is directed to a sump region between the inner chamber and the outer chamber. The sump gas can include argon. The volume of the inner region can be sealed from the sump region. In an instance, the process gas inlet(s), exhaust outlet, and silicon ribbon exit extend through the sump region and are sealed against the outer chamber. Feedstock replenishment, windows, probes, or actuators also can be sealed to maintain the environment in the outer chamber and inner chamber.

The ribbon can be separated from the melt at a wall of the crucible where a stable meniscus forms. The ribbon can be pulled through a silicon ribbon exit defined by the inner chamber. The ribbon is formed at a same rate as the pulling. A gas curtain can be applied at the silicon ribbon exit. The gas curtain can use nitrogen or other gases.

Heat can be applied to a volume of the inner chamber using heaters in the sump region.

Evaporated gas from a volume of the inner chamber can be removed through an exhaust outlet, such as with a flow of process gas. SiO can be removed from the evaporated gas from the process gas using a filtering system. The process gas from the filtering system can be recycled in the system.

Low oxygen interstitial concentrations in the ribbon are possible using the method 300. In an example, the oxygen interstitial concentration for a silicon ribbon produced using the method 300 was from 1-2 ppma.

Embodiments disclosed herein can include a processor that controls the various components of the system 100, such as the gas flows, pressures, filtering system operations, or temperatures. For example, the processor can control heaters, pullers, valves, pumps, or blowers in the system 100. In some embodiments, various steps, functions, and/or operations of system and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor (or computer system) or, alternatively, multiple processors (or multiple computer systems). Moreover, different sub-systems of the system may include one or more computing or logic systems. Therefore, the above description should not be interpreted as a limitation on the present disclosure but merely an illustration.

A silicon-quartz-SiO system is described with the liquid to be solidified and an evaporated gas, but the same principles can apply to other systems such as sapphire-molybdenum-AlOₓ, sapphire-tungsten-AlOₓ, germanium-quartz-GeOₓ, gallium oxide-iridium-GaOₓ, etc. Thus, other evaporated species are possible.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An apparatus for forming a crystalline ribbon grown on a surface of a melt comprising:
an inner chamber defining a process gas inlet, an exhaust outlet, and a silicon ribbon exit;
a crucible configured to hold a melt, wherein the crucible is disposed in a volume of the inner chamber;
a cold initializer facing an exposed surface of the melt, wherein the cold initializer is disposed in a volume of the inner chamber;
a process gas feed in fluid communication with the process gas inlet;
an outer chamber, wherein the outer chamber surrounds at least part of the inner chamber and defines an opening for the process gas feed and a sump inlet;
a plurality of heaters disposed in a sump region between an interior surface of the outer chamber and an exterior surface of the inner chamber; and
a sump gas feed in fluid communication with the sump inlet, wherein the sump gas feed is configured to deliver a sump gas to the sump region.

2. The apparatus of claim 1, further comprising insulation disposed in the sump region.

3. The apparatus of claim 1, wherein the outer chamber defines a sump exhaust in fluid communication with the sump region.

4. The apparatus of claim 1, wherein the volume of the inner chamber is sealed from the sump region.

5. The apparatus of claim 1, further comprising a process gas source in fluid communication with the process gas feed, wherein the process gas source includes helium and/or hydrogen.

6. The apparatus of claim 1, further comprising a sump gas source in fluid communication with the sump gas feed, wherein the sump gas source includes argon.

7. The apparatus of claim 1, wherein an interior surface of the inner chamber includes a coating, and wherein the coating includes SiC, BN, and/or TaC.

8. The apparatus of claim 1, wherein the outer chamber defines an opening for the exhaust outlet.

9. The apparatus of claim 8, wherein the exhaust outlet is configured to remove evaporated gas and the process gas from the volume of the inner chamber.

10. The apparatus of claim 9, further comprising a filtering system configured to remove the evaporated gas from the process gas.

11. The apparatus of claim 10, further comprising a recycle feed configured to recycle process gas from the filter.

12. The apparatus of claim 1, further comprising a gas curtain at the silicon ribbon exit.

13. The apparatus of claim 12, wherein the gas curtain uses nitrogen.

14. A method comprising:
providing a melt in a crucible, wherein the crucible is disposed in an inner chamber, and wherein the inner chamber is disposed at least partly within an outer chamber;
forming a ribbon floating on the melt using a cold initializer facing an exposed surface of the melt, wherein the ribbon is single crystal;
directing a process gas to a volume of the inner chamber through the inner chamber and the outer chamber; and
directing a sump gas to a sump region between the inner chamber and the outer chamber.

15. The method of claim 14, further comprising pulling the ribbon through a silicon ribbon exit defined by the inner chamber, wherein the ribbon is formed at a same rate as the pulling.

16. The method of claim 15, further comprising applying a gas curtain at the silicon ribbon exit.

17. The method of claim 16, wherein the gas curtain uses nitrogen.

18. The method of claim 14, further comprising separating the ribbon from the melt at a wall of the crucible where a stable meniscus forms.

19. The method of claim 14, further comprising applying heat to a volume of the inner chamber using heaters in the sump region.

20. The method of claim 14, wherein the volume of the inner chamber is sealed from the sump region.

21. The method of claim 14, wherein the process gas includes helium and/or hydrogen.

22. The method of claim 14, wherein the sump gas includes argon.

23. The method of claim 14, further comprising removing evaporated gas and the process gas from a volume of the inner chamber through an exhaust outlet.

24. The method of claim 23, further comprising removing the evaporated gas from the process gas using a filtering system.

25. The method of claim 24, further comprising recycling the process gas from the filtering system.
